(19) United States
(12) Patent Application Publication
(10) Pub. No.: US 2026/0123249 A1
(43) Pub. Date: Apr. 30, 2026

(54) Display Panel and Display Device Including the Same

(71) Applicant: LG Display Co., Ltd., Seoul (KR)

(72) Inventors: Kwang Hyun Choi, Paju-si (KR); Chang Soo Kim, Paju-si (KR); Seong Yeong Kim, Paju-si (KR)

(21) Appl. No.: 19/076,658

(22) Filed: Mar. 11, 2025

(30) Foreign Application Priority Data
Oct. 30, 2024 (KR) 10-2024-0150939

(51) Int. Cl. H10K 59/80; H10K 59/88

(52) U.S. Cl. CPC H10K 59/879; H10K 59/88

(57) ABSTRACT

A display device includes a display panel comprising a first pixel region; a second pixel region; and a boundary pixel region disposed between the first pixel region and the second pixel region, wherein each of the first pixel region, the second pixel region, and the boundary pixel region includes a plurality of pixels composed of a plurality of sub-pixels, each of the boundary pixel region and the second pixel region includes a plurality of light transmission parts between the plurality of sub-pixels, a plurality of first lenses are disposed in the first pixel region, a plurality of second lenses are disposed in the boundary pixel region, and a plurality of third lenses are disposed in the second pixel region, and a size of a lens increases gradationally in an order of the plurality of first lenses, the plurality of second lenses, and the plurality of third lenses.

### CROSS-REFERENCE TO RELATED APPLICATION

This application claims priority to and the benefit of Republic of Korea Patent Application No. 10-2024-0150939, filed on Oct. 30, 2024, which is hereby incorporated by reference in its entirety.

### BACKGROUND

### 1. Field of Technology

The present specification relates to a display panel and a display device including the same.

### 2. Discussion of Related Art

Electroluminescent display devices are classified into inorganic light-emitting display devices or organic light-emitting display devices according to a material of a light-emitting layer. An active matrix type organic light-emitting diode display device includes organic light emitting diodes (hereinafter referred to as an “OLEDs”) for emitting light by themselves and has advantages of having a fast response speed, high luminous efficiency and luminance, and a wide viewing angle.

An OLED display device has OLEDs formed in each pixel. Since the OLED display device has a fast response speed and excellent luminous efficiency, luminance, viewing angle, etc. and can exhibit a black grayscale in full black, the OLED display device has an excellent contrast ratio and color reproducibility.

### SUMMARY

Recently, a technology in which a low pixel density region is provided in a display panel and optical devices are disposed below this region has been proposed. This technology can implement a full screen display because optical devices are disposed below regions in which images are displayed, but a boundary between high pixel density regions can be visible, and luminance and color can be perceived differently between the regions.

Embodiments of the present specification are directed to providing a display panel in which boundary visual perception is improved by using a lens gain by designing the size of a lens to increase gradationally from a first pixel region (a normal region (NML)) to a second pixel region (a under display camera (UDC)) via a boundary pixel region (a boundary region (BDR)), and a display device including the same.

Objects of embodiments of the present specification are not limited to the above-described objects, and other objects that are not mentioned will be able to be clearly understood by those skilled in the art based on the following description.

According to various embodiments of the present specification, there is provided a display panel including a first pixel region, a second pixel region, and a boundary pixel region disposed between the first pixel region and the second pixel region, wherein each of the first pixel region, the second pixel region, and the boundary pixel region includes a plurality of pixels composed of a plurality of sub-pixels, each of the boundary pixel region and the second pixel region includes a plurality of light transmission parts between the plurality of sub-pixels, a plurality of first lenses are disposed in the first pixel region, a plurality of second lenses are disposed in the boundary pixel region, a plurality of third lenses are disposed in the second pixel region, and a size of a lens increases gradationally in an order of the plurality of first lenses, the plurality of second lenses, and the plurality of third lenses.

According to various embodiments of the present specification, there is provided a display device including a display panel including a first pixel region, a second pixel region, and a boundary pixel region disposed between the first pixel region and the second pixel region and a circuit layer connected to pixels disposed in the first pixel region, the second pixel region, and the boundary pixel region of the display panel, wherein each of the pixels of the first pixel region, the second pixel region, and the boundary pixel region includes a plurality of sub-pixels, each of the boundary pixel region and the second pixel region includes a plurality of light transmission parts between the plurality of sub-pixels, a plurality of first lenses are disposed in the first pixel region, a plurality of second lenses are disposed in the boundary pixel region, a plurality of third lenses are disposed in the second pixel region, and a size of the lens increases gradationally in an order of the plurality of first lenses, the plurality of second lenses, and the plurality of third lenses.

Detailed items according to various examples of the present specification other than the above-described configuration are included in the following description and the accompanying drawings.

### BRIEF DESCRIPTION OF THE DRAWINGS

The above and other objects, features, and advantages of the present specification will become more apparent to those of ordinary skill in the art by describing exemplary embodiments thereof in detail with reference to the accompanying drawings, in which:

FIG. 1 is a view illustrating an optical device overlapping a second pixel region of a display panel according to an embodiment of the present specification;

FIG. 2 is a view illustrating an example of optical devices disposed in the second pixel region and a notch region of the display panel according to an embodiment of the present specification;

FIG. 3 is an enlarged plan view of a part of the display panel according to one embodiment of the present specification;

FIG. 4 is a plan view of an arrangement of a plurality of lenses of the display panel according to one embodiment of the present specification;

FIG. 5 is an enlarged plan view of the arrangement of the plurality of lenses of the display panel according to one embodiment of the present specification;

FIG. 6 is a cross-sectional view illustrating first and second pixel regions and a boundary pixel region in the display panel according to one embodiment of the present specification;

FIG. 7 is an enlarged cross-sectional view illustrating lenses gradationally disposed in each pixel region of the display panel according to one embodiment of the present specification;

FIG. 8 is an enlarged cross-sectional view illustrating a pixel region and a light transmission part of the display panel according to one embodiment of the present specification;

FIG. 9 is a view illustrating a color difference improvement effect of the boundary pixel region of the display panel according to one embodiment of the present specification;

FIG. 10 is a plan view illustrating the arrangement of a plurality of lenses of a display panel according to another embodiment of the present specification;

FIG. 11 is an enlarged plan view illustrating the arrangement of the plurality of lenses in each pixel region of the display panel according to another embodiment of the present specification;

FIG. 12 is a cross-sectional view of each pixel region of the display panel according to another embodiment of the present specification;

FIG. 13 is an enlarged cross-sectional view illustrating lenses gradationally disposed in each pixel region of the display panel according to another embodiment of the present specification;

FIG. 14 is a view illustrating first to third panel parts of a full dashboard type display device according to still another embodiment of the present specification;

FIG. 15 is a cross-sectional view illustrating first and second pixel regions and the boundary pixel region of the first and second panel parts of FIG. 14 according to one embodiment of the present specification;

FIG. 16 is an enlarged cross-sectional view illustrating lenses gradationally disposed in each pixel region of the display panel of FIG. 15 according to one embodiment of the present specification;

FIG. 17 is a cross-sectional view illustrating first and second pixel regions and a boundary pixel region of a third panel part of FIG. 14 according to one embodiment of the present specification; and

FIG. 18 is an enlarged cross-sectional view illustrating lenses gradationally disposed in each pixel region of the third panel part of FIG. 17 according to one embodiment of the present specification.

### DETAILED DESCRIPTION

Advantages and features of the present specification and methods for achieving them will become clear by referencing embodiments described below in detail in conjunction with the accompanying drawings. However, the present specification is not limited to embodiments disclosed below but will be implemented in various different forms, and these embodiments are merely provided to make the specification of the present specification complete and fully inform those skilled in the art to which the present specification pertains of the scope of the present invention.

Since shapes, sizes, ratios, angles, numbers, etc. disclosed in the drawings for describing the embodiments of the present specification are illustrative, the present specification is not limited to the illustrated items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “include,” and the like described herein are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When a positional relationship is described, for example, when the positional relationship between two parts is described using “on,” “above,” “under,” “next to,” etc., one or more other parts may be located between the two parts, for example, unless “immediately,” “directly,” or “close to” is used.

When a temporal relationship is described, when the temporal relationship is described using “after,” “subsequently,” “then,” “before,” or etc., it may also include a non-consecutive case unless “immediately” or “directly” is used.

Although terms such as first and second are used to describe various components, these components are not limited by these terms. These terms are only used to distinguish one component from another component. Therefore, a first component described below may be a second component within the technical spirit of the present specification.

In the description of components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between components that may be connected, coupled, joined, or attached indirectly unless otherwise stated specifically.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specifically.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, and various technological interworking and driving are made possible, and the embodiments may be implemented independently of each other or implemented together in an associated relationship.

A pixel circuit and a gate driving unit (e.g., a gate driving circuit) that are formed on a display panel of the present specification may include a plurality of transistors. The transistors may be implemented as an oxide thin film transistor (TFT) including an oxide semiconductor, a low temperature polysilicon (LTPS) TFT, etc. Each of the transistors may be implemented as a p-channel TFT or an n-channel TFT.

A transistor is a three-electrode element including a gate, a source, and a drain. The source is an electrode for supplying carriers to the transistor. The carriers start to move from the source in the transistor. The drain is an electrode through which the carriers move from the transistor to the outside. In the transistor, the carriers move from the source to the drain. In the case of an n-channel transistor, since the carriers are electrons, a source voltage is lower than a drain voltage so that the electrons move from the source to the drain. In the n-channel transistor, a direction of a current flows from the drain to the source. In the case of a p-channel transistor (PMOS), since the carriers are holes, the source voltage is higher than the drain voltage so that the holes move from the source to the drain. In the p-channel transistor, a current flows from the source to the drain because the holes move from the source to the drain. It should be noted that the source and drain of the transistor are not fixed. For example, the source and the drain may vary according to an applied voltage. Accordingly, the specification is not limited by the source and drain of the transistor. In the following description, the source and drain of the transistor are referred to as “first and second electrodes.”

A gate signal may swing between a gate on voltage and a gate off voltage. The gate on voltage is set to be a voltage higher than a threshold voltage of the transistor, and the gate off voltage is set to be a voltage lower than the threshold voltage of the transistor. The transistor is turned on in response to the gate on voltage, while the transistor is turned off in response to the gate off voltage. In the case of the n-channel transistor, the gate on voltage may be a gate high voltage VGH/VEH, and the gate off voltage may be a gate low voltage VGL/VEL. In the case of the p-channel transistor, the gate on voltage may be a gate low voltage VGL/VEL, and the gate off voltage may be the gate high voltage VGH/VEL.

Hereinafter, various embodiments of the present specification will be described in detail with reference to the accompanying drawings.

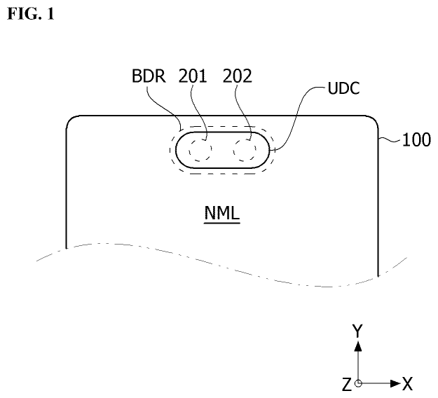

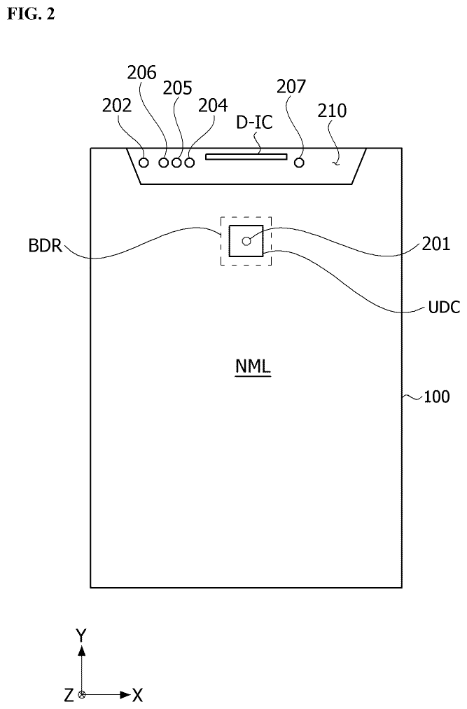

FIG. 1 is a view illustrating an optical device overlapping a second pixel region UDC of a display panel according to an embodiment of the present specification. FIG. 2 is a view illustrating an example of optical devices disposed in the second pixel region UDC and a notch region of the display panel according to an embodiment of the present specification.

Referring to FIGS. 1 and 2, a pixel array that forms a screen of a display panel 100 may include a first pixel region NML and the second pixel region UDC. The first pixel region NML and the second pixel region UDC may include pixels on which pixel data of an input image is written. Accordingly, the input image may be displayed in the first pixel region NML and the second pixel region UDC.

The first pixel region NML may be a display region in which a plurality of pixels are disposed to reproduce the input image. The first pixel region NML may be larger than the second pixel region UDC and may be a main display region of a screen on which most images are displayed. A pixel density of the second pixel region UDC may be the same as or lower than that of the first pixel region NML. The pixel density may be represented by pixels per inch (PPI).

The second pixel region UDC may include a plurality of second light transmission parts TA2 (see FIG. 6) without a medium that blocks light, but is not limited thereto. The second light transmission part TA2 may be disposed between sub-pixels. Light may pass through the second light transmission part TA2 with almost no loss thereof. When the light transmission part of the second pixel region UDC is larger to increase the amount of light received by an optical device through the second pixel region UDC, the pixel density is decreased due to a region of the light transmission part, and thus the pixel density or resolution of the second pixel region UDC may be lower than that of the first pixel region NML.

Each of the pixels of the first pixel region NML and the second pixel region UDC may include sub-pixels of different colors in order to implement the colors of the images. The sub-pixels may include red, green, and blue sub-pixels. Hereinafter, the red sub-pixel is referred to as a R sub-pixel, the green sub-pixel is referred to as a G sub-pixel, and the blue sub-pixel is referred to as a B sub-pixel. Each pixel P may further include a white sub-pixel. Each sub-pixel may include a pixel circuit for driving a light-emitting element.

One or more optical devices 200 may be disposed under a rear surface of the display panel 100 to overlap the second pixel region UDC of the display panel 100. External light may travel through the second pixel region UDC to the optical device 200 disposed under the display panel 100. The optical device 200 may include one or more of an image sensor (or a camera), a proximity sensor, a white light illumination device, and an optical device for facial recognition.

The optical device 200 for facial recognition may include an infrared light source, an infrared camera, an infrared illumination device, etc., which is disposed under the second pixel region UDC of the display panel 100. In FIG. 1, a reference numeral 201 may be an infrared light source, and a reference numeral 202 may be an infrared camera, but the embodiments of the present specification are not limited thereto. In the example of FIG. 2, an ambient light sensor 204, a proximity sensor 205, a flood illuminator 206, the infrared camera 202, and a front camera 207 may be disposed in a notch region 210 of a mobile terminal, and the infrared light source 201 may be disposed in the second pixel region UDC. The notch region 210 may be a non-display region without having pixels at an upper end of a screen of a mobile terminal.

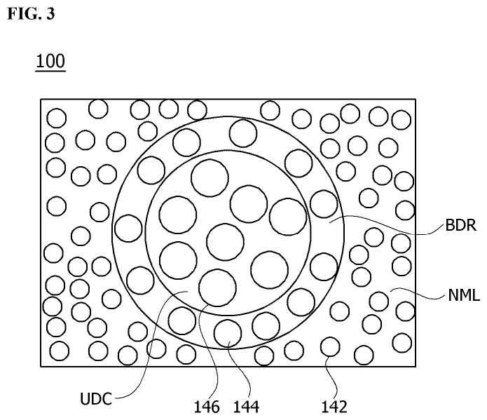

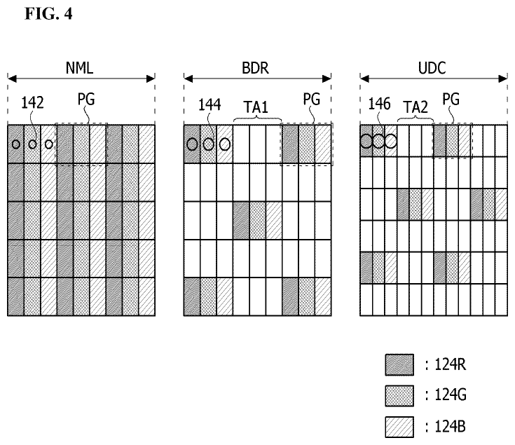

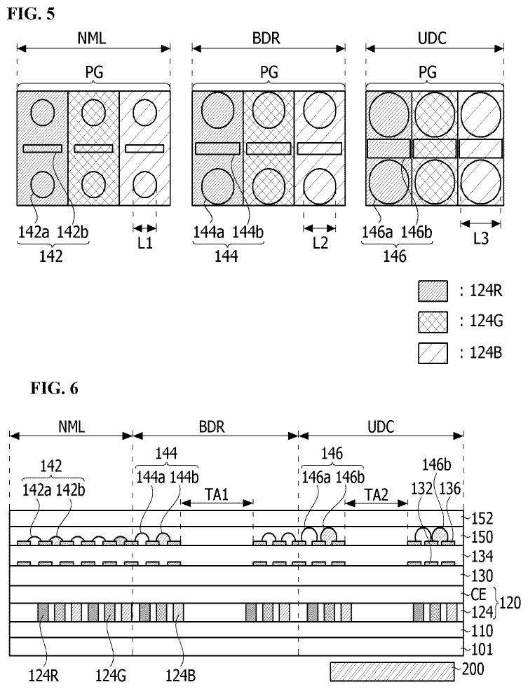

FIG. 3 is an enlarged plan view of a part of the display panel according to one embodiment of the present specification. FIG. 4 is a plan view of an arrangement of a plurality of lenses of the display panel according to one embodiment of the present specification. FIG. 5 is an enlarged plan view of the arrangement of the plurality of lenses of the display panel according to one embodiment of the present specification.

Referring to FIGS. 3 to 5, the display panel 100 according to the present specification may include the first pixel region NML, the second pixel region UDC, and the boundary pixel region BDR between the first pixel region NML and the second pixel region UDC.

Specifically, the first pixel region NML may include a plurality of pixels. Each pixel may be implemented as a real-type pixel in which one pixel includes red (R), green (G), and blue (B) sub-pixels 124R, 124G, and 124B of three primary colors. Each pixel may further include a W sub-pixel that is omitted from the drawings. A pixel density of the first pixel region NML may be higher than that of the second pixel region UDC.

The luminous efficiency of a light-emitting element of a sub-pixel may differ with respect to each color. Considering this matter, the size of the sub-pixel may vary for each color. For example, among the R, G, and B sub-pixels, the B sub-pixel 124B may be the largest, and the G sub-pixel 124G may be the smallest. However, the present embodiment is not limited thereto.

Referring to FIGS. 3 to 5, a pixel group PG disposed in the first pixel region NML may include a plurality of sub-pixels 124R, 124G, and 124B.

In addition, a plurality of first convex lenses 142 may be disposed in the first pixel region NML. Specifically, the plurality of first lenses 142 may be disposed above the plurality of sub-pixels 124R, 124G, and 124B located in the first pixel region NML. The plurality of first lenses 142 may include at least one 1-1 lens 142a and at least one 2-2 lens 142b.

For example, among the plurality of first lenses 142, the at least one 1-1 lens 142a may be formed as a hemispherical lens, and the at least one 1-2 lens 142b may be formed as a bar-typed lens, such as a cylindrical lens. However, the 1-2 bar-typed lens 142b may be provided or omitted on a case-by-case basis. That is, the plurality of first lenses 142 may be composed of at least one 1-1 lens 142a and the 1-2 bar-typed lens 142b or composed of only at least one 1-1 lens 142a.

For example, referring to FIG. 5, the plurality of first lenses 142 disposed in the red sub-pixel 124R may include at least one 1-1 hemispherical lens 142a and at least one 1-2 bar-typed lens 142b. In the present specification, an example in which the first lens 142 is composed of two 1-1 lenses 142a and one 1-2 lens 142b is described, but the present specification is not limited thereto.

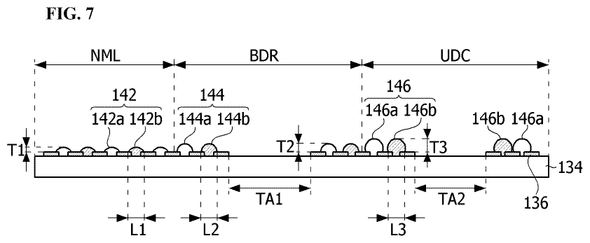

The 1-1 hemispherical lens 142a may serve to block up/down and left/right viewing angles and condense light. In addition, the 1-2 bar-typed lens 142b may serve to block the up and down viewing angles. However, the present embodiment is not limited thereto. For example, the first lens 142 including at least one 1-1 convex lens 142a and at least one 1-2 convex lens 142b may be disposed above the plurality of sub-pixels 124R, 124G, and 124B. Referring to FIG. 5, at least one first lens 142 may have, for example, a first length L1, which is a maximum length in a horizontal direction, and a first thickness T1 (see FIG. 7), which is a maximum thickness in a vertical direction. Here, in the same manner, the first length L1 may be applied to the 1-1 lens 142a and the 1-2 lens 142b constituting the plurality of first lenses 142. The boundary pixel region BDR may include pixel groups PG spaced a predetermined distance from each other and the first light transmission parts TA1 disposed between the neighboring pixel groups PG. The pixel group PG disposed in the boundary pixel region BDR may include a plurality of sub-pixels 124R, 124G, and 124B.

The first light transmission part TA1 may be a region without having pixels. The first light transmission part TA1 may be formed of a transparent insulation material without including a metal line or a pixel. Due to the first light transmission parts TA1, the pixel density of the boundary pixel region BDR may be lower than that of the first pixel region NML. However, the present embodiment is not necessarily limited thereto.

In the boundary pixel region BDR, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of second convex lenses 144 may be disposed in the boundary pixel region BDR. Specifically, the plurality of second lenses 144 may be disposed above the plurality of sub-pixels 124R, 124G, and 124B located in the boundary pixel region BDR. The plurality of second lenses 144 may include at least one 2-1 lens 144a and at least one 2-2 lens 144b.

For example, at least one second lens 144 may be disposed on the sub-pixel 124R. In addition, at least one second lens 144 may be disposed on the sub-pixel 124G. At least one second lens 144 may also be disposed on the sub-pixel 124B. However, the present embodiment is not limited thereto.

For example, among the plurality of second lenses 144, the at least one 2-1 lens 144a may be formed as a hemispherical lens, and the at least one 2-2 lens 144b may be formed as a bar-typed lens, such as a cylindrical lens. However, the 2-2 bar-typed lens 144b may be provided or omitted on a case-by-case basis. That is, the plurality of second lenses 144 may be composed of at least one 2-1 lens 144a and the 2-2 bar-typed lens 144b or composed of only at least one 2-1 lens 144a.

For example, referring to FIG. 5, the plurality of second lenses 144 disposed in the red sub-pixel 124R may include at least two 2-1 hemispherical lenses 144a and at least one 2-2 bar-type lens 144b. In the present specification, an example in which the second lens 144 is composed of two 2-1 lenses 144a and one 1-2 lens 144b is described, but the present specification is not limited thereto.

The 2-1 hemispherical lens 144a may serve to block up/down and left/right viewing angles and condense light. In addition, the 2-2 bar-typed lens 144b may serve to block the up and down viewing angles. However, the present embodiment is not limited thereto.

Referring to FIG. 5, the plurality of second lenses 144 may each have, for example, a second length L2, which is a maximum length in the horizontal direction, and a second thickness T2 (see FIG. 7), which is a maximum thickness in the vertical direction. For example, the second length L2 of each of the plurality of second lenses 144 may be greater than the first length L1 of the first lens 142 of the first pixel region NML. In addition, a second thickness T2 of each of the plurality of second lenses 144 in the vertical direction may be greater than the first thickness T1 of the first lens 142 of the first pixel region NML. Here, in the same manner, the second length L2 may be applied to the 2-1 lens 144a and the 2-2 lens 144b constituting the plurality of second lenses 144.

Referring to FIGS. 3 to 5, the second pixel region UDC may include pixel groups PG spaced a predetermined distance from each other and second light transmission parts TA2 disposed between the neighboring pixel groups PG. The pixel group PG disposed in the second pixel region UDC may include a plurality of sub-pixels 124R, 124G, and 124B.

The second light transmission part TA2 may be a region without having pixels. The second light transmission part TA2 may be formed of a transparent insulation material without including a metal line or a pixel. Due to the second light transmission parts TA2, the pixel density of the second pixel region UDC may be lower than that of the first pixel region NML. However, since an average light transmittance of the first pixel region NML may be greater than that of the second pixel region UDC, the amount of light received by the optical devices 200 can be increased.

In the second pixel region UDC, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of third convex lenses 146 may be disposed in the second pixel region UDC. Specifically, the plurality of third lenses 146 may be disposed above the plurality of sub-pixels 124R, 124G, and 124B located in the second pixel region UDC. The plurality of third lenses 146 may include at least one 3-1 lens 146a and at least one 3-3 lens 146b.

For example, among the plurality of third lenses 146, the at least one 3-1 lens 146a may be formed as a hemispherical lens, and the at least one 3-2 lens 146b may be formed as a bar-typed lens, such as a cylindrical lens. However, the 3-2 bar-typed lens 146b may be provided or omitted on a case-by-case basis. That is, the plurality of third lenses 146 may be composed of at least one 3-1 lens 146a and the 3-2 bar-typed lens 142b or composed of only at least one 3-1 lens 146a.

For example, referring to FIG. 5, the plurality of third lenses 146 disposed in the red sub-pixel 124R may include at least two 3-1 hemispherical lenses 146a and at least one 3-2 bar-type lens 146b. In the present specification, an example in which the third lens 146 is composed of two 3-1 lenses 146a and one 3-2 lens 142b is described, but the present specification is not limited thereto.

The 3-1 hemispherical lens 146a may serve to block up/down and left/right viewing angles and condense light. In addition, the 3-2 bar-typed lens 146b may serve to block the up and down viewing angles. However, the present embodiment is not limited thereto. For example, the third lens 146 including at least one 3-1 convex lens 146a and at least one 3-2 convex lens 146b may be disposed above a plurality of sub-pixels 124R, 124G, and 124B. Referring to FIG. 5, at least one third lens 146 may have, for example, a third length L3, which is a maximum length in the horizontal direction, and a third thickness T3 (see FIG. 7), which is a maximum thickness in the vertical direction. Here, in the same manner, the third length L3 may be applied to the 3-1 lens 146a and the 3-2 lens 146b constituting the plurality of third lenses 146.

For example, the third length L3 of each of the plurality of third lenses 146 may be greater than the first length L1 of the first lens 142 of the first pixel region NML and the second length L2 of the second lens 144 of the boundary pixel region BDR. In addition, the third thickness T3 of each of the plurality of third lenses 146 may be greater than the first thickness T1 of the first lens 142 of the first pixel region NML and the second thickness T2 of the second lens 144 of the boundary pixel region BDR.

Accordingly, the sizes of the first to third lenses 142, 144, and 146 of the display panel of the present specification may be designed to increase gradationally from the first pixel region NML to the second pixel region UDC via the boundary pixel region BDR. The sizes of the first to third lenses 142, 144, and 146 of the display panel 100 may include not only the first to third lengths L1, L2, and L3 and the first to third thicknesses T1, T2, and T3, but also first to third regions (not illustrated). In this case, the first region may be a region of the first lens 142, a second region may be a region of the second lens 144, and the third region may be a region of the third lens 146.

According to the present specification, by designing the sizes, for example, the lengths and thicknesses, of the first to third lenses 142, 144, and 146 to gradationally increase from the first pixel region NML to the second pixel region UDC via the boundary pixel region BDR, it is possible to improve boundary visual perception in the boundary pixel region BDR using a lens gain.

Referring to FIGS. 4 and 5, an example in which the first pixel is composed of R, G, and B sub-pixels 124R, 124G, and 124B is illustrated, but the present embodiment is not limited thereto. An emission region in the pixel group PG may be determined to be the total of emission regions connected to the sub-pixels in the pixel group PG.

The shape and size of the emission region of each color in each pixel of the first and second pixel regions NML and UDC may be determined by a fine metal mask (FMM). The emission region for each color in the pixel group PG of the second pixel region UDC may be designed to be substantially the same as the first pixel region NML or designed to have a different shape and/or size from the emission region of the first pixel region NML using an FMM having a different shape from the first pixel region NML.

The shapes of the first and second light transmission parts TA1 and TA2 are exemplified as being circular, but they are not limited thereto. For example, the light transmission parts TA1 and TA2 may be designed in various shapes, such as a circle, oval, polygon, etc.

Referring to FIGS. 4 and 5, a pixel array of the display panel 100 may further include the first pixel region NML, the second pixel region UDC, and the boundary pixel region BDR of a predetermined size, which is disposed between the first pixel region NML and the second pixel region UDC.

The boundary pixel region BDR may be a pixel region of a predetermined size between the first pixel region NML and the second pixel region UDC. The boundary pixel region BDR may include a plurality of pixels. As illustrated in FIG. 3, the pixel density of the boundary pixel region BDR may be designed to be lower than that of the first pixel region NML and higher than or equal to that of the second pixel region UDC. However, the present embodiment is not limited thereto.

At least one of a pixel density, a pixel size, and maximum luminance of the pixel may be different between the first pixel region NML and the second pixel region UDC. Accordingly, the boundary pixel region BDR may be perceived as being different from the first pixel region NML and the second pixel region UDC.

Referring to FIGS. 4 and 5, to reduce the phenomenon of the boundary pixel region BDR being perceived, the sizes of the first, second, and third lenses 142, 144, and 146 disposed in the first pixel region NML, the boundary pixel region BDR, and the second pixel region UDC may be designed to be different from each other.

Specifically, referring to FIG. 5, the plurality of first lenses 142 may be disposed above the sub-pixels 124R, 124G, and 124B located in the first pixel region NML. In addition, the plurality of second lenses 144 may be disposed above the sub-pixels 124R, 124G, and 124B located in the boundary pixel region BDR. The plurality of third lenses 146 may be disposed above the sub-pixels 124R, 124G, and 124B located in the second pixel region UDC.

In addition, the sizes of the first lenses 142 may be smaller than the sizes of the second lenses 144, and the sizes of the second lenses 144 may be smaller than the sizes of the third lenses 146. For example, the size of the lens may be designed to increase gradationally from the first lenses 142 to the third lenses 146 via the second lenses 144.

For example, the sizes of the first to third lenses 142, 144, and 146 may include a length, a thickness, and/or an area. However, the present embodiment is not limited thereto. For example, the first length L1 of each of the first lenses 142 may be smaller than the second length L2 of each of the second lenses 144, and the second length L2 of each of the second lenses 144 may be smaller than the third length L3 of each of the third lenses 146. In addition, the first thickness T1 of each of the first lenses 142 may be smaller than the second thickness T2 of each of the second lenses 144, and the second thickness T2 of each of the second lenses 144 may be smaller than the third thickness T3 of each of the third lenses 146.

In this way, according to the present specification, the sizes of the lens may be designed to increase gradationally from the first lenses 142 to the third lenses 146 via the second lenses 144, thereby reducing the phenomenon of the boundary pixel region BDR being perceived.

According to the present specification, by designing the sizes of the lenses to increase gradationally from the first lenses 142 to the third lenses 146 via the second lenses 144, it is possible to increase the degree of freedom in applying a boundary compensation algorithm for luminance gradation.

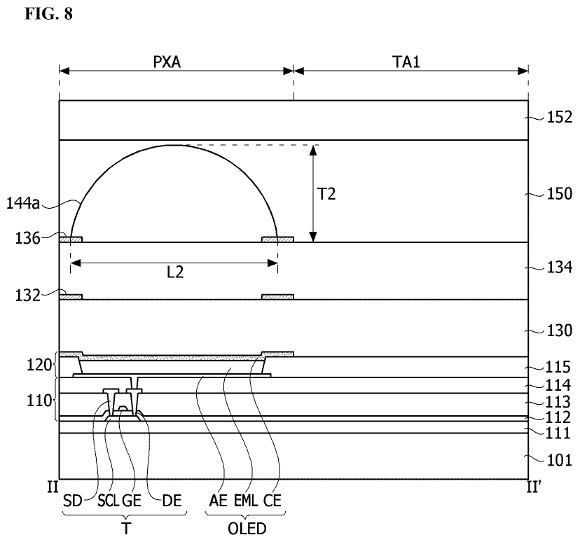

FIG. 6 is a cross-sectional view illustrating first and second pixel regions and a boundary pixel region in the display panel according to one embodiment of the present specification. FIG. 7 is an enlarged cross-sectional view illustrating lenses gradationally disposed in each pixel region of the display panel according to one embodiment of the present specification. FIG. 8 is an enlarged cross-sectional view illustrating a pixel region and a light transmission part of the display panel according to one embodiment of the present specification.

Referring to FIGS. 6 to 8, in the display device of the present specification, since the optical devices 200 are disposed below the rear surface of the display panel 100 to overlap the second pixel region UDC, the display region of the screen does not have restrictions caused by the optical devices 200.

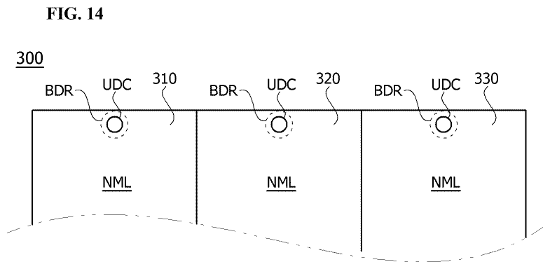

Accordingly, as illustrated in FIG. 14, the display device of the present specification may implement a screen of a full dashboard type display device 300 (see FIG. 14) by expanding a display region of the screen and increase the degree of freedom related to a screen design.

The display panel 100 (see FIG. 2) has a width in an X-axis direction, a length in a Y-axis direction, and a thickness in a Z-axis direction. The X-axis direction and the Y-axis direction may be orthogonal on a flat surface of the display panel 100.

The display panel 100 (see FIG. 2) may include a circuit layer 110 disposed on the substrate 101 and a light-emitting element layer 120 disposed on the circuit layer 110. A polarizing plate may be disposed on the light-emitting element layer 120, and a cover glass (not illustrated) may be disposed on the polarizing plate.

The circuit layer 110 may include pixel circuits connected to lines, such as data lines, gate lines intersecting the data lines, power lines, and the like, gate drivers connected to the gate lines, and the like. The circuit layer 110 may include transistors implemented as a TFT and circuit devices such as a capacitor. The lines and circuit devices of the circuit layer 110 may be implemented as a plurality of insulating layers, two or more metal layers with an insulating layer interposed therebetween, and an active layer containing a semiconductor material.

Specifically, referring to FIG. 8, in one embodiment of the present specification, a buffer layer 111 may be disposed on the substrate 101.

A gate insulating film 112 and an interlayer insulating film 113 may be disposed on the buffer layer 111. Each of the gate insulating film 112 and the interlayer insulating film 113 may be formed of an inorganic insulating film containing an inorganic material or an organic insulating film containing an organic material.

The light-emitting element layer 120 may include a light-emitting element that is driven by a pixel circuit. The light-emitting element may be implemented as an OLED. The light-emitting element OLED may include first and second electrodes AE and CE and an emission layer EML provided between the two electrodes AE and CE. The emission layer EML may include a hole injection layer (HIL), a hole transport layer (HTL), an emission layer (EML), an electron transport layer (ETL), and an electron injection layer (EIL) but is not limited thereto. When a voltage is applied to anode and cathode electrodes of the light-emitting element OLED, holes that have passed through the hole transport layer (HTL) and electrons that have passed through the electron transport layer (ETL) may move to the emission layer (EML) to form excitons so that visible light is emitted from the emission layer (EML). The OLED used as the light-emitting element may have a tandem structure in which a plurality of emission layers are stacked. The light-emitting element OLED having the tandem structure can increase the luminance and lifetime of a pixel. A light-emitting element layer 14 may further include a color filter array for selectively transmitting waves of a red, green, or blue color.

The light-emitting element OLED may include the first and second electrodes AE and CE and the emission layer EML provided between the two electrodes AE and CE. Here, one of the first and second electrodes AE and CE may be an anode electrode, and the other may be a cathode electrode. Here, the first electrode AE may be used as the anode electrode, and the second electrode CE may be used as the cathode electrode. However, the present embodiment is not limited thereto.

When the light-emitting element OLED is a top emission type organic light emitting diode, the first electrode AE may be a reflective electrode and the second electrode CE may be a transmissive electrode. In the embodiment of the present specification, an example in which the light-emitting element OLED is a top emission type light-emitting element and the first electrode AE is an anode electrode will be described.

The first electrode AE may be electrically connected to a terminal DE of a transistor T through a contact hole passing through a protective film 114. The first electrode AE may include a reflective film (not illustrated) capable of reflecting light and a transparent conductive film (not illustrated) disposed above or under the reflective film. At least one of the transparent conductive film and the reflective film may be electrically connected to the terminal DE of the transistor T.

The display device may further include a bank 115 having an opening exposing a part of the first electrode AE, such as an upper surface of the first electrode AE.

In a first pixel area NML, a boundary pixel area BDR and a second pixel area UDC, each of first to third sub-pixels 124R to 124B included in each of the unit pixel may include an emission area (not shown) and a non-emission area (not shown) adjacent to the emission area. The non-emission area may surround the emission area. In the present embodiment, the emission area may be defined to correspond to a part of the first electrode AE or the emission layer EML, which is exposed by an opening of a bank 115.

The emission layer EML may be disposed in a region corresponding to the opening of the bank 115. That is, the emission layer EML may be individually provided to each of the plurality of sub-pixels 124R, 124G, and 124B. The emission layer EML may contain an organic material and/or an inorganic material. In one embodiment of the present specification, a patterned emission layer EML is illustrated as an example, but the emission layer EML may be provided in common to pixels PXLs according to an embodiment. A color of light generated from the emission layer EML may be one of red, green, blue, and white, but the present embodiment is not limited thereto. For example, the color of the light generated from the emission layer EML may be one of magenta, cyan, and yellow.

The second electrode CE is formed on the emission layer EML. The second electrode CE may be provided in common to each of the plurality of first to third sub-pixels 124R, 124G, and 124B. The second electrode CE may be provided in a plate shape to entirely correspond to the first display area A1, but the present invention is not limited thereto. A hole injection layer (not illustrated) may be disposed between the first electrode AE and the emission layer EML, and an electron injection layer (not illustrated) may be disposed between the emission layer EML and the second electrode CE. The hole injection layer and the electron injection layer may be provided in common to each of the plurality of sub-pixels 124R, 124G, and 124B.

A thin film encapsulation layer 130 may be disposed on the light-emitting element layer 120 including the second electrode CE. The thin film encapsulation layer 130 may include a plurality of insulating films covering the light-emitting element OLED. The thin film encapsulation layer 130 may have a multi-insulating film structure in which organic films and inorganic films are alternately stacked. The inorganic film can block penetration of moisture or oxygen. For example, the organic film may planarize a surface of the inorganic film. When the organic film and the inorganic film are stacked in multiple layers, a movement path of moisture or oxygen may be longer than that of a single layer, thereby effectively blocking the penetration of moisture/oxygen affecting the light-emitting element layer 120.

A black matrix 132 may be disposed on the thin film encapsulation layer 130. The black matrix 132 may be disposed to cover a part of the thin film encapsulation layer 130, which does not overlap the emission layer EML of the light-emitting element OLED. However, the present specification is not limited thereto.

In addition, a planarization layer 134 may be disposed on the black matrix 132 and the thin film encapsulation layer 130. The planarization layer 134 may be formed of the same inorganic film or organic film as the thin film encapsulation layer 130. However, the present embodiment is not limited thereto.

A sensor metal layer 136 may be disposed on the planarization layer 134. The sensor metal layer 136 may be disposed at a location that overlaps the black matrix 132 without overlapping the emission layer EML.

In addition, the second convex lens 144 may be disposed on the planarization layer 134 that overlaps the emission layer EML of the light-emitting element layer 120, which constitutes a region between the sensor metal layers 136. The second convex lens 144 may be disposed on the boundary pixel region BDR. Here, an example in which the second lens 144 disposed in the boundary pixel region BDR is described, but the first lens 142 and the second lens 144 may also be disposed in the first pixel region NML and the second pixel region UDC, respectively.

For example, although not illustrated in the drawings, when manufacturing the plurality of first to third lenses 142, 144, and 146, the lenses may be manufactured by forming a high-refractive lens material layer, forming a low-refractive planarization layer thereon, and then patterning the low-refractive planarization layer and the high-refractive lens material layer. The first to third lenses 142, 144, and 146 may curve light that has transmitted the high-refractive lens material layer that is incident on the low-refractive planarization layer and condensed in a desired direction. However, the present embodiment is not limited thereto.

An insulating film 150 may be disposed on the planarization layer 134 including the second lens 144 and the sensor metal layer 136. The insulating film 150 may insulate intersecting portions of metal line patterns and planarize surfaces of the sensor metal layer 136 and the second lenses 144. Here, the case of the second lens 144 may also be applied in the same manner to the first and third lenses 142 and 146 of FIG. 6.

A polarizing plate 152 may be disposed on the insulating film 150. The polarizing plate 152 may convert polarization of external light reflected by a metal of a sensor metal layer 136 and a circuit layer 110, thereby increasing visibility and a contrast ratio. The polarizing plate 152 may be implemented as a polarizing plate or a circular polarizing plate in which a linear polarizing plate and a phase retardation film are bonded. A cover glass (not illustrated) may be adhered on the polarizing plate 152.

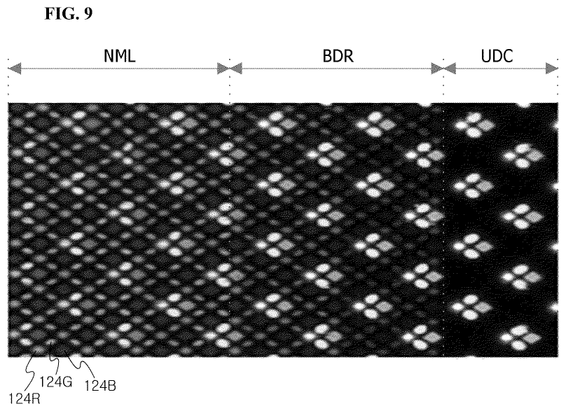

FIG. 9 is a view illustrating a color difference improvement effect of the boundary pixel region of the display panel according to one embodiment of the present specification.

Referring to FIG. 9, according to the display panel of the present specification, the second lenses 144 in the boundary pixel region BDR may be gradationally designed to be larger than the first lenses 142 in the first pixel region NML and smaller than the third lenses 146 in the second pixel region UDC, thereby significantly improving color difference visual perception in the boundary pixel region BDR. For example, by designing the sizes of the first, second, and third lenses 142, 144, and 146 to increase gradationally from the first pixel region NML to the second pixel region UDC via the boundary pixel region BDR, it is possible to reduce a luminance difference in each boundary region, thereby improving the color difference visual perception in the boundary pixel region BDR.

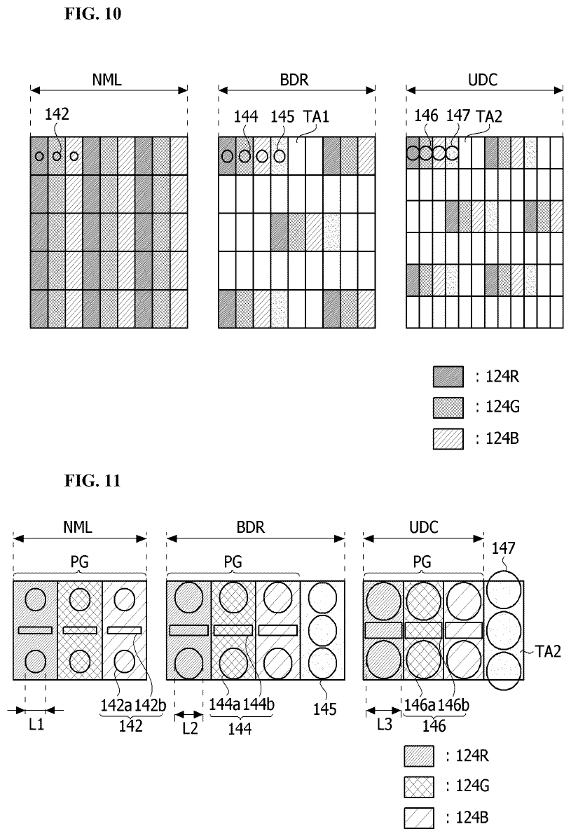

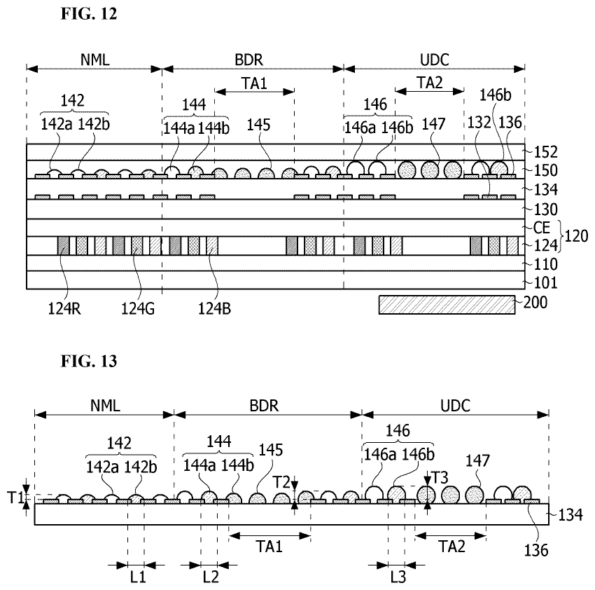

FIG. 10 is a plan view illustrating an arrangement of a plurality of lenses of a display panel according to another embodiment of the present specification. FIG. 11 is an enlarged plan view illustrating the arrangement of the plurality of lenses in each pixel region of the display panel according to another embodiment of the present specification. FIG. 12 is a cross-sectional view of each pixel region of the display panel according to another embodiment of the present specification. FIG. 13 is an enlarged cross-sectional view illustrating lenses gradationally disposed in each pixel region of the display panel according to another embodiment of the present specification.

Another embodiment of the present specification may include the same components as FIGS. 3 to 5 according to the embodiments of the present specification except for the configuration in which first and second dummy lenses are additionally disposed in the first light transmission part TA1 and the second light transmission part TA2 of the boundary pixel region BDR in order to improve reflective visual perception in a lens off state. Hereinafter, description of the circuit layer 110 and the light-emitting element layer 120 that are disposed above the substrate 101 will be omitted.

Referring to FIG. 10, a display panel according to another embodiment of the present specification may include the first pixel region NML, the second pixel region UDC, and the boundary pixel region BDR between the first pixel region NML and the second pixel region UDC.

Specifically, the first pixel region NML may include a plurality of pixels. Each pixel may be implemented as a real-type pixel in which one pixel includes the R, G, and B sub-pixels 124R, 124G, and 124B of three primary colors. Each pixel may further include a W sub-pixel that has been omitted from the drawings. A pixel density of the first pixel region NML may be higher than that of the second pixel region UDC.

The luminous efficiency of light-emitting elements of the sub-pixels may differ for each color. Considering this matter, the size of the sub-pixel may vary for each color. For example, among the R, G, and B sub-pixels, the B sub-pixel 124B may be the largest, and the G sub-pixel 124G may be the smallest. However, the present embodiment is not limited thereto.

Referring to FIGS. 10 and 11, the pixel group PG disposed in the first pixel region NML may include a plurality of sub-pixels 124R, 124G, and 124B.

A plurality of first convex lenses 142 may be disposed in the first pixel region NML. Specifically, the plurality of first lenses 142 may be disposed above the plurality of sub-pixels 124R, 124G, and 124B located in the first pixel region NML. The plurality of first lenses 142 may include at least one 1-1 lens 142a and at least one 1-2 lens 142b.

For example, among the plurality of first lenses 142, the at least one 1-1 lens 142a may be formed as a hemispherical lens, and the at least one 1-2 lens 142b may be formed as a bar-typed lens, such as a cylindrical lens. However, the 1-2 bar-typed lens 142b may be provided or omitted on a case-by-case basis. That is, the plurality of first lenses 142 may be composed of at least one 1-1 lens 142a and the 1-2 bar-typed lens 142b or composed of only at least one 1-1 lens 142a.

For example, referring to FIGS. 11 and 12, the plurality of first lenses 142 disposed in the red sub-pixel 124R may include at least two 1-1 hemispherical lenses 142a and at least one 1-2 bar-type lens 142b. In the present specification, an example in which the first lens 142 is composed of two 1-1 lenses 142a and one 1-2 lens 142b is described, but the present specification is not limited thereto.

The hemispherical type 1-1 lens 142a may serve to block upper, lower, left, and right viewing angles and condense light. In addition, the 1-2 bar-typed lens 142b may serve to block the up and down viewing angles. However, the present embodiment is not limited thereto. For example, the first lens 142 including at least one 1-1 convex lens 142a and at least one 1-2 convex lens 142b may be disposed above the plurality of sub-pixels 124R, 124G, and 124B.

Referring to FIG. 13, at least one first lens 142 may have, for example, the first length L1, which is a maximum length in the horizontal direction, and the first thickness T1, which is a maximum thickness in the vertical direction. Here, in the same manner, the first length L1 may be applied to at least one 1-1 lens 142a and at least one 1-2 lens 142b constituting the plurality of third lenses 142.

Referring to FIGS. 10 and 11, the boundary pixel region BDR may include the pixel groups PG spaced a predetermined distance from each other and the first light transmission parts TA1 disposed between the neighboring pixel groups PG. The pixel group PG disposed in the boundary pixel region BDR may include a plurality of sub-pixels 124R, 124G, and 124B.

The first light transmission part TA1 may include a region without having pixels. The first light transmission part TA1 may be formed of a transparent insulation material without including a metal line or a pixel. Due to the first light transmission parts TA1, the pixel density of the boundary pixel region BDR may be lower than that of the first pixel region NML. However, the present embodiment is not necessarily limited thereto.

In the boundary pixel region BDR, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of second convex lenses 144 and a plurality of first convex dummy lenses 145 may be disposed in the boundary pixel region BDR. Specifically, the plurality of second lenses 144 and the plurality of first dummy lenses 145 may be disposed above the plurality of sub-pixels 124R, 124G, and 124B located in the boundary pixel region BDR. The plurality of first dummy lenses 145 may be disposed in the first light transmission part TA1 of the boundary pixel region BDR.

Here, the first dummy lens 145 may be disposed to improve the boundary visual perception in the off state.

The plurality of second lenses 144 may include at least one 2-1 lens 144a and at least one 2-2 lens 144b.

For example, among the plurality of second lenses 144, the at least one 2-1 lens 144a may be formed as a hemispherical lens, and the at least one 2-2 lens 144b may be formed as a bar-typed lens, such as a cylindrical lens. However, the 2-2 bar-typed lens 144b may be provided or omitted on a case-by-case basis. That is, the plurality of second lenses 144 may be composed of at least one 2-1 lens 144a and the 2-2 bar-typed lens 144b or composed of only at least one 2-1 lens 144a.

For example, referring to FIGS. 12 and 13, the plurality of second lenses 144a disposed in the red sub-pixel 124R may include at least two 2-1 hemispherical lenses 144a and at least one 2-2 bar-type lens 144b. In the present specification, an example in which the second lens 144 is composed of two 2-1 lenses 144a and one 1-2 lens 144b is described, but the present specification is not limited thereto.

The 2-1 hemispherical lens 144a may serve to block up/down and left/right viewing angles and condense light. In addition, the 2-2 bar-typed lens 144b may serve to block the up and down viewing angles. However, the present embodiment is not limited thereto. For example, the second lens 144 including at least one 2-1 convex lens 144a and at least one 2-2 convex lens 144b may be disposed above a plurality of sub-pixels 124R, 124G, and 124B.

Referring to FIG. 13, the at least one second lens 144 and each of the plurality of first dummy lenses 145 may have, for example, the second length L2, which is a maximum length in the horizontal direction, and the second thickness T2, which is a maximum thickness in the vertical direction. Here, the second length L2 may be applied to the 2-1 lens 144a and the 2-2 lens 144b constituting the plurality of second lenses 144. For example, the second length L2 of the second lens 144 and the first dummy lens 145 may be greater than the first length L1 of the first pixel region NML. In addition, the second thickness T2 of the second lens 144 may be greater than the first thickness T1 of the first pixel region NML.

The second pixel region UDC may include the pixel groups PG spaced a predetermined distance from each other and second light transmission parts TA2 disposed between the neighboring pixel groups PG. The pixel group PG disposed in the second pixel region UDC may include a plurality of sub-pixels 124R, 124G, and 124B.

The second light transmission part TA2 may be a region without having pixels. The second light transmission part TA2 may be formed of a transparent insulation material without including a metal line or a pixel. Due to the second light transmission parts TA2, the pixel density of the second pixel region UDC may be lower than that of the first pixel region NML. However, since the average light transmittance of the first pixel region NML may be greater than that of the second pixel region UDC, the amount of light received by the optical devices 200 can be increased.

In the second pixel region UDC, the pixel group PG may include three or more pixels and emit light with luminance corresponding to a grayscale of pixel data. Each pixel of the pixel group PG may include three or four sub-pixels. However, the present embodiment is not limited thereto.

In the second pixel region UDC, a plurality of third convex lenses 146 and a plurality of second convex dummy lenses 147 may be disposed in the second pixel region UDC. Specifically, the plurality of third lenses 146 and the plurality of second dummy lenses 147 may be disposed above the plurality of sub-pixels 124R, 124G, and 124B located in the second pixel region UDC. However, the present embodiment is not limited thereto. For example, the plurality of second dummy lenses 147 may not be disposed in the second pixel region UDC. Here, the second dummy lens 147 may be disposed to improve the boundary visual perception in the off state.

The plurality of second lenses 146 may include at least one 3-1 lens 146a and at least one 3-3 lens 146b.

For example, among the plurality of third lenses 146, the at least one 3-1 lens 146a may be formed as a hemispherical lens, and the at least one 3-3 lens 146b may be formed as a bar-typed lens, such as a cylindrical lens. However, the 3-2 bar-typed lens 146b may be provided or omitted on a case-by-case basis. That is, the plurality of third lenses 146 may be composed of at least one 3-1 lens 146a and the 3-2 bar-typed lens 146b or composed of only at least one 3-1 lens 146a.

For example, referring to FIGS. 12 and 13, the plurality of third lenses 146a disposed in the red sub-pixel 124R may include at least two 3-1 hemispherical lenses 146a and at least one 3-2 bar-type lens 146b. In the present specification, an example in which the third lens 146 is composed of two 3-1 lenses 146a and one 3-2 lens 146b has been described, but the present specification is not limited thereto.

The 3-1 hemispherical lens 146a may serve to block up/down and left/right viewing angles and condense light. In addition, the 3-2 bar-type lens 146b may serve to block the up and down viewing angles. However, the present embodiment is not limited thereto. For example, the third lens 146 including at least one 3-1 convex lens 146a and at least one 3-2 convex lens 146b may be disposed above the plurality of sub-pixels 124R, 124G, and 124B.

Referring to FIG. 13, the at least one third lens 146 and the second dummy lens 147 may have, for example, the third length L3, which is a maximum length in the horizontal direction, and the third thickness T3, which is a maximum thickness in the vertical direction. Here, in the same manner, the third length L3 may be applied to the 3-1 lens 146a and the 3-2 lens 146b constituting the plurality of third lenses 146. However, the present embodiment is not limited thereto.

For example, the third length L3 of each of the plurality of third lenses 146 and the second dummy lens 147 may be greater than the first length L1 of the first lens 142 of the first pixel region NML and the second length L2 of the second lens 144 and the first dummy lens 145 of the boundary pixel region BDR. The third thickness T3 of each of the plurality of third lenses 146 may be greater than the first thickness T1 of the first lens 142 of the first pixel region NML and the second thickness T2 of the second lens 144 of the boundary pixel region BDR. The present embodiment is not limited thereto.

Specifically, referring to FIGS. 11 and 12, an example in which the first pixel is composed of the R, G, and B sub-pixels 124R, 124G, and 124B is illustrated, but the present embodiment is not limited thereto. An emission region in the pixel group PG may be determined to be the total of emission regions connected to the sub-pixels in the pixel group PG.

The shape and size of the emission region of each color in each pixel of the first and second pixel regions NML and UDC may be determined by an FMM. The emission region for each color in the pixel group PG of the second pixel region UDC may be designed to be substantially the same as the first pixel region NML or designed to have a different shape and/or size from the emission region of the first pixel region NML using an FMM having a different shape from the first pixel region NML.

The shapes of the first and second dummy lenses 145 and 147 of the first and second light transmission parts TA1 and TA2 are exemplified as being circular, but the shapes thereof are not limited thereto. For example, the first and second dummy lenses 145 and 147 of the first and second light transmission parts TA1 and TA2 may be designed in various shapes, such as hemispherical, elliptical, and polygonal shapes.

Referring to FIGS. 10 and 11, the pixel array of the display panel 100 may further include the first pixel region NML, the second pixel region UDC, and the boundary pixel region BDR of a predetermined size, which is disposed between the first pixel region NML and the second pixel region UDC.

The boundary pixel region BDR may be a pixel region of a predetermined size between the first pixel region NML and the second pixel region UDC. The boundary pixel region BDR may include a plurality of pixels. The pixel density of the boundary pixel region BDR may be designed to be lower than that of the first pixel region NML or higher than or equal to that of the second pixel region UDC. However, the present embodiment is not limited thereto.

At least one of a pixel density, a pixel size, and maximum luminance of the pixel may be different between the first pixel region NML and the second pixel region UDC. Accordingly, the boundary pixel region BDR may be perceived as being different from the first pixel region NML and the second pixel region UDC.

Specifically, referring to FIG. 12, the plurality of first lenses 142 may be disposed above the sub-pixels 124R, 124G, and 124B located in the first pixel region NML. For example, the plurality of first lenses 142 may be disposed on the insulating film 134 between the sensor metal layers 136 overlapping the emission layer EML.

In addition, the plurality of second lenses 144 may be disposed above the sub-pixels 124R, 124G, and 124B located in the boundary pixel region BDR. For example, the plurality of second lenses 144 may be disposed on the insulating film 134 between the sensor metal layers 136 overlapping the emission layer EML located in the boundary pixel region BDR.

Referring to FIGS. 10 to 13, the plurality of first and second dummy lenses 145 and 147 may be disposed in the first light transmission part TA1 of the boundary pixel region BDR and the second light transmission part TA2 of the second pixel region UDC. For example, the plurality of first and second dummy lenses 145 and 147 may be disposed on the insulating film 134 located in the first light transmission part TA1 of the boundary pixel region BDR and the second pixel region UDR. The black matrix 132 and the sensor metal layer 136 are not present on the insulating film 134 located in the first light transmission part TA1 and the second light transmission part TA2. However, the present embodiment is not limited thereto.

Referring to FIGS. 12 and 13, the plurality of third lenses 146 may be disposed above the sub-pixels 124R, 124G, and 124B located in the second pixel region UDC. For example, the plurality of third lenses 146 may be disposed on the insulating film 134 between the sensor metal layers 136 overlapping the emission layer EML located in the second pixel region UDC.

In addition, the sizes of the first lenses 142 may be smaller than the sizes of the second lenses 144 and the first dummy lenses 145, and the sizes of the second lenses 144 and the first dummy lenses 145 may be smaller than the sizes of the third lenses 146 and the second dummy lenses 147. For example, the sizes of the lenses may be designed to increase gradationally from the first lenses 142 to the third lenses 146 and the second dummy lenses 147 via the second lenses 144 and the first dummy lenses 145.

For example, the sizes of the first to third lenses 142, 144, and 146 and the first and second dummy lenses 145 and 147 may include a length, a thickness, and/or an area. However, the present embodiment is not limited thereto. For example, the first length L1 of each of the first lenses 142 may be smaller than the second length L2 of each of the second lenses 144 and each of the first dummy lenses 145, and the second length L2 of each of the second lenses 144 and each of the first dummy lens 145 may be smaller than the third length L3 of each of the third lens 146 and each of the second dummy lenses 147. In addition, the first thickness T1 of each of the first lenses 142 may be smaller than the second thickness T2 of each of the second lenses 144 and each of the first dummy lenses 145, and the second thickness T2 of each of the second lenses 144 and each of the first dummy lenses 145 may be smaller than the third thickness T3 of each of the third lenses 146 and each of the second dummy lenses 147.

Accordingly, according to the present specification, the sizes of the lenses may be designed to increase gradationally from the first lenses 142 to the third lenses 146 and the second dummy lenses 147 via the second lenses 144 and the first dummy lenses 145, thereby reducing the phenomenon of the boundary pixel region BDR being perceived.

According to the present specification, by designing the sizes, such as the lengths and thicknesses, of the first to third lenses 142, 144, and 146 to gradationally increase from the first pixel region NML to the second pixel region UDC via the boundary pixel region BDR, it is possible to improve boundary visual perception in the boundary pixel region BDR using a lens gain.

According to the present specification, by additionally arranging the first dummy lenses 145 in the first light transmission part TA1 of the boundary pixel region BDR, it is possible to improve reflection visual perception in a lens off state. In particular, in the case of the second pixel region UDC, since the high-refractive transmittance in the IR region is about 90% or higher, the first dummy lens 145 may be additionally disposed in the first light transmission part TA1 of the boundary pixel region BDR in order to improve the lens off state.

According to the present specification, the sizes of the lenses may be designed to increase gradationally from the first lenses 142 to the third lenses 146 and the second dummy lenses 147 via the second lenses 144 and the first dummy lenses 145, thereby improving the degree of freedom in applying a boundary compensation algorithm for luminance gradation.

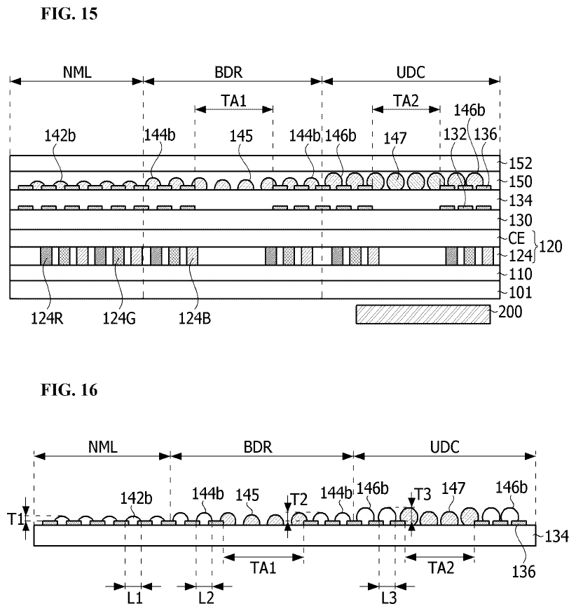

FIG. 14 is a view illustrating first to third panel parts of a full dashboard type display device according to still another embodiment of the present specification. FIG. 15 is a cross-sectional view illustrating the first and second pixel regions and the boundary pixel region of the first and second panel parts of FIG. 14 according to one embodiment. FIG. 16 is an enlarged cross-sectional view illustrating lenses gradationally disposed in each pixel region of the display panel of FIG. 15 according to one embodiment.

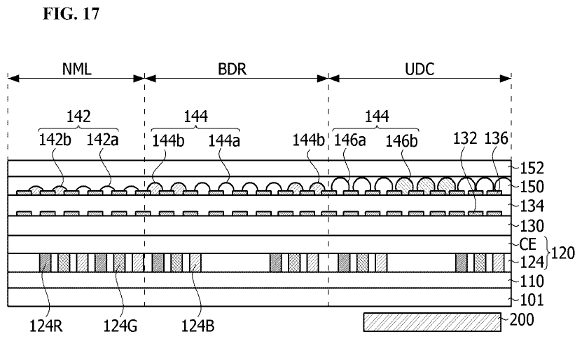

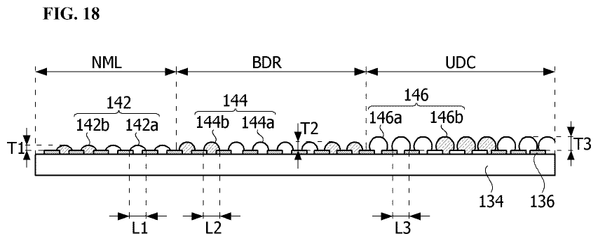

FIG. 17 is a cross-sectional view illustrating first and second pixel regions and a boundary pixel region of a third panel part of FIG. 14 according to one embodiment. FIG. 18 is an enlarged cross-sectional view illustrating lenses gradationally disposed in each pixel region of the third panel part of FIG. 17 according to one embodiment.

Referring to FIG. 14, a display panel (300) according to still another embodiment of the present specification may be, for example, a full dashboard type display device and may include a first panel part 310 that is a cluster part, a second panel part 320 that is a CID part, and a third panel part 330 that is a CDD part (SPM). Here, the first panel part 310 may include a panel region located at a driver's dashboard side of a vehicle. In addition, the second panel part 320 may include a panel region between a driver's seat and a front passenger seat. The third panel part 330 may include a panel region of the front passenger seat. However, the present embodiment is not limited thereto.

Referring to FIGS. 14 to 16, the first to third panel parts 310, 320, and 330 of the display panel 300 according to still another embodiment of the present specification may include the first pixel region NML, the second pixel region UDC, and the boundary pixel region BDR between the first pixel region NML and the second pixel region UDC.

Specifically, the first pixel region NML may include a plurality of pixels. Each pixel may be implemented as a real-type pixel in which one pixel includes the R, G, and B sub-pixels 124R, 124G, and 124B of three primary colors. Each pixel may further include a W sub-pixel that has been omitted from the drawings. A pixel density of the first pixel region NML may be greater than that of the second pixel region UDC.

The luminous efficiency of light-emitting elements of the sub-pixels may differ with respect to each color. In consideration of this, the size of the sub-pixel may vary for each color. For example, among the R, G, and B sub-pixels, the B sub-pixel 124B may be the largest, and the G sub-pixel 124G may be the smallest. However, the present embodiment is not limited thereto.

Referring to FIGS. 15 and 16, the pixel groups (not illustrated, PG in FIG. 11) disposed in the first pixel region NML, the boundary pixel region BDR, and the second pixel region UDC of the first to third panel parts 310, 320, and 330 may each include the plurality of sub-pixels 124R, 124G, and 124B.

In the first pixel regions NMLs of the first and second panel parts 310 and 320, a plurality of 1-2 convex lenses 142b may be disposed; in the boundary pixel region BDR, a plurality of 2-2 convex lenses 144b and a plurality of first convex dummy lenses 145 may be disposed; and in the second pixel region UDC, a plurality of 3-2 convex lenses 146b and a plurality of second convex dummy lenses 147 may be disposed.

Here, the 1-2, 2-2, and 3-2 lenses 142b, 144b, and 146b may be SPM share lenses and may include bar-typed lenses, such as cylindrical lenses. The SPM share lens may serve to prevent the visual perception of the driver from being reduced due to external light reflection at the driver's side via up and down viewing angle control. However, the present embodiment is not limited thereto.

Specifically, at least one 1-2 lens 142b may be disposed above the plurality of sub-pixels 124R, 124G, and 124B located in the first pixel regions NMLs of the first and second panel parts 310 and 320. However, the present embodiment is not limited thereto.

Referring to FIGS. 15 and 16, at least one 1-2 lens 142b has the first length L1 in the horizontal direction. In addition, the 1-2 lens 142b may have the first thickness T1 in the vertical direction (see FIG. 16).

Referring to FIGS. 15 and 16, the boundary pixel region BDR of the first and second panel parts 310 and 320 may include pixel groups (not illustrated, PG of FIG. 11) spaced a predetermined distance from each other and first light transmission parts TA1 disposed between neighboring pixel groups PG. The pixel group PG disposed in the boundary pixel region BDR may include a plurality of sub-pixels 124R, 124G, and 124B.

The first light transmission part TA1 may include a region without having pixels. The first light transmission part TA1 may be formed of a transparent insulation material without including a metal line or a pixel. Due to the first light transmission parts TA1, the pixel density of the boundary pixel region BDR may be lower than that of the first pixel region NML. However, the present embodiment is not necessarily limited thereto.

In the boundary pixel region BDR, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of 2-2 convex lenses 144b and a plurality of first convex dummy lenses 145 may be disposed in the boundary pixel region BDR. Specifically, the plurality of 2-2 lenses 144b and the plurality of first dummy lenses 145 may be disposed above the plurality of sub-pixels 124R, 124G, and 124B located in the boundary pixel region BDR. The plurality of first dummy lenses 145 may be disposed in the first light transmission part TA1 of the boundary pixel region BDR.

The plurality of 2-2 lenses 144b may be formed as bar-typed lenses, such as cylindrical lenses.

Referring to FIGS. 15 and 16, the at least one 2-2 lens 144b and the plurality of first dummy lenses 145 may have, for example, the second length L2, which is a maximum length in the horizontal direction, and the second thickness T2, which is a maximum thickness in the vertical direction.

Referring to FIGS. 15 and 16, the plurality of 2-2 lenses 144b and the plurality of first dummy lenses 145 of the boundary pixel region BDR may have the second length L2 in the horizontal direction and the second thickness T2 in the vertical direction. For example, the second length L2 of each of the plurality of 2-2 lenses 144b and the first dummy lens 145 of the boundary pixel region BDR may be greater than the first length L1 of each of the plurality of 1-2 lenses 142b of the first pixel region NML. In addition, the second thickness T2 of each of the plurality of 2-2 lenses 144b and the first dummy lens 145 of the boundary pixel region BDR may be greater than the first thickness T1 of each of the plurality of 1-2 lenses 142b of the first pixel region NML.

Referring to FIGS. 15 and 16, the second pixel regions UDC of the first and second panel parts 310 and 320 may include pixel groups (not illustrated, PG of FIG. 11) spaced a predetermined distance from each other and the second light transmission parts TA2 disposed between neighboring pixel groups PG. The pixel group PG disposed in the second pixel region UDC may include a plurality of sub-pixels 124R, 124G, and 124B.

The second light transmission part TA2 may be a region without having pixels. The second light transmission part TA2 may be formed of a transparent insulation material without including a metal line or a pixel. Due to the second light transmission parts TA2, the pixel density of the second pixel region UDC may be lower than that of the first pixel region NML. However, since the average light transmittance of the first pixel region NML may be greater than that of the second pixel region UDC, the amount of light received by the optical devices 200 can be increased.

In the second pixel region UDC, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of 3-2 convex lenses 146b and a plurality of second convex dummy lenses 147 may be disposed in the second pixel region UDC. Specifically, at least one 3-2 lens 146b may be disposed above the plurality of sub-pixels 124R, 124G, and 124B located in the second pixel region UDC. The second dummy lenses 147 may be disposed in the second light transmission part TA2. However, the present embodiment is not limited thereto.

Referring to FIG. 16, the plurality of 3-2 lenses 146b and the plurality of second dummy lenses 147 may each have the third length L3 in the horizontal direction and the third thickness T3 in the vertical direction. For example, the third length L3 of each of the plurality of 3-2 lenses 146b and each of the plurality of second dummy lenses 147 of the second pixel region UDC may be greater than the first length L1 of the 1-2 lens 142b of the first pixel region NML and the second length L2 of each of the plurality of 2-2 lenses 144b and the first dummy lens 145. In addition, the third thickness T3 of each of the plurality of 3-2 lenses 146b and each of the second dummy lens 147 of the second pixel region UDC may be greater than the first thickness T1 of the 1-2 lens 142b of the first pixel region NML and the second thickness T2 of each of the plurality of 2-2 lenses 144b and the first dummy lens 145 of the boundary pixel region BDR.

Accordingly, in the present specification, by providing the 1-2, 2-2, and 3-2 lenses 142b, 144b, and 146b including a bar-typed lens, such as a cylindrical lens, which is an SPM share lens, it is possible to prevent the visual perception of the driver from being reduced due to external light reflection at the driver's side via up and down viewing angle control.

Referring to FIGS. 14, 17, and 18, the pixel groups (not illustrated, PG of FIG. 11) disposed in the first pixel region NML, the boundary pixel region BDR, and the second pixel region UDC of the third panel part 330 may include the plurality of sub-pixels 124R, 124G, and 124B.

A plurality of first convex lenses 142 may be disposed in the first pixel region NML. In addition, a plurality of second convex lenses 144 may be disposed in the boundary pixel region BDR. A plurality of third convex lenses 146 may be disposed in the second pixel region UDC.

The plurality of first lenses 142 may include at least one 1-1 lens 142a and at least one 1-2 lens 142b. In addition, the plurality of second lenses 144 may include at least one 2-1 lens 144 and at least one 2-2 lens 148. The plurality of third lenses 146 may include at least one 3-1 lens 146a and at least one 3-2 lens 146b.

Here, the 1-1 lenses 142a, the 2-1 lenses 144a, and the 3-1 lenses 146a may include hemispherical lenses.

In addition, the 1-1, 2-1, and 3-1 lenses 142a, 144a, and 146a may include hemispherical lenses as SPM privacy lens. The SPM privacy lens may serve to block the up/down and left/right viewing angles. However, the present embodiment is not limited thereto.

The 1-2, 2-2, and 3-2 lenses 142b, 144b, and 146b may be SPM share lenses and may include bar-typed lenses, such as cylindrical lenses. The SPM share lens may serve to prevent the visual perception of the driver from being reduced due to external light reflection at the driver's side via up and down viewing angle control. However, the present embodiment is not limited thereto.

For example, the sizes of the first to third lenses 142, 144, and 146, for example, the share lenses, may be designed to increase gradationally from the first pixel region NML to the second pixel region UDC via the boundary pixel region BDR, thereby reducing a luminance increase range. However, the present embodiment is not limited thereto.

Specifically, at least two 1-1 lenses 142a and at least one 1-2 lens 142b may be disposed above each of the plurality of sub-pixels 124R, 124G, and 124B located in the first pixel region NML. However, the present embodiment is not limited thereto. Referring to FIG. 18, the plurality of 1-1 and 1-2 lenses 142a and 142b may each have the first length L1 and the first thickness T1.

Referring to FIGS. 17 and 18, the boundary pixel region BDR may include the pixel groups (not illustrated, PG of FIG. 11) spaced a predetermined distance from each other. The pixel group PG disposed in the boundary pixel region BDR may include a plurality of sub-pixels 124R, 124G, and 124B.

The boundary pixel region BDR has no region without having pixels. However, the present embodiment is not necessarily limited thereto. For example, a plurality of dummy lenses may be disposed in the boundary pixel region BDR.

In the boundary pixel region BDR, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of 2-1 convex lenses 144a and 2-2 convex lenses 144b may be disposed in the boundary pixel region BDR. Specifically, at least one 2-1 lens 144a and at least one 2-2 lens 144b may be disposed above each of the plurality of sub-pixels 124R, 124G, and 124B located in the boundary pixel region BDR. However, the present embodiment is not limited thereto.

In addition, the 2-1 lenses 146a may include hemispherical lenses as the SPM privacy lens. The SPM privacy lens may serve to block the up/down and left/right viewing angles. However, the present embodiment is not limited thereto.

In addition, the 2-2 lenses 144b may be SPM share lenses and may include bar-typed lenses, such as cylindrical lenses. The SPM share lens may serve to prevent the visual perception of the driver from being reduced due to external light reflection at the driver's side via up and down viewing angle control. However, the present embodiment is not limited thereto.

Referring to FIG. 18, the plurality of 2-1 lenses 144a and 2-2 lenses 144b of the boundary pixel region BDR may each have the second length L2 and the second thickness T2. For example, the second length L2 of each of the plurality of 2-1 lenses 144a and each of the plurality of 2-2 lenses 144b of the boundary pixel region BDR may be greater than the first length L1 of each of the 1-1 and 1-2 lenses 142a and 142b of the first pixel region NML. In addition, the second thickness T2 of each of the plurality of 2-2 lenses 144a and each of the plurality of 2-2 lenses 144b of the boundary pixel region BDR may be greater than the first thickness T1 of each of the 2-1 and 2-2 lenses 142a and 142b of the first pixel region NML.

Referring to FIG. 17, in the second pixel region UDC, the pixel groups (not illustrated, PG of FIG. 11) spaced a predetermined distance from each other may include the plurality of sub-pixels 124R, 124G, and 124B.

In the second pixel region UDC, the pixel group PG may include three or more pixels and emit light with luminance corresponding to a grayscale of pixel data. Each pixel of the pixel group PG may include three or four sub-pixels. However, the present embodiment is not limited thereto.

In addition, a plurality of third convex lenses 146 may be disposed in the second pixel region UDC. Specifically, the plurality of third convex lenses 146 may include at least one 3-1 lens 146a and at least one 3-2 lens 146b. However, the present embodiment is not limited thereto.

In addition, the 3-1 lenses 146a may include hemispherical lenses as the SPM privacy lens. The SPM privacy lens may serve to block the up/down and left/right viewing angles. However, the present embodiment is not limited thereto.

In addition, the 3-2 lenses 146b may be SPM share lenses and may include bar-typed lenses, such as cylindrical lenses. The SPM share lens may serve to prevent the visual perception of the driver from being reduced due to external light reflection at the driver's side via up and down viewing angle control. However, the present embodiment is not limited thereto.

Referring to FIG. 18, the plurality of 3-1 lenses 146a and the plurality of 3-2 lenses 146b may each have the third length L3 in the horizontal direction and the third thickness T3 in the vertical direction. For example, the third length L3 of each of the plurality of 3-1 lenses 146a and each of the plurality of second lenses 144 of the second pixel region UDC may be greater than the first length L1 of the 1-1 and 1-2 lenses 142a and 142b of the first pixel region NML and the second length L2 of each of the plurality of 2-1 and 2-2 lenses 144a and 144b. In addition, the third thickness T3 of each of the plurality of 3-1 lenses 146a and 3-2 lenses 146b of the second pixel region UDC may be greater than the first thickness T1 of the 1-1 and 1-2 lenses 142a and 142b of the first pixel region NML and the second thickness T2 of each of the plurality of 2-2 lenses 144a and 2-1 lenses 144b of the boundary pixel region BDR.

In this way, according to still another embodiment of the present specification, by additionally arranging the first and second dummy lenses 145 and 147 in the first light transmission part TA1 and the second light transmission part TA2 of the boundary pixel region BDR and the second pixel region UDC, which are disposed in each of the first and second panel parts 310 and 320 of the full dashboard type display device, it is possible to improve visual perception in the boundary pixel region BDR and the second pixel region UDC.

In addition, according to still another embodiment of the present specification, by arranging the privacy lenses 142b, 144b, and 146b gradationally in the first pixel region NML, the boundary pixel region BDR, and the second pixel region UDC of the third panel part 330, it is possible to reduce circuit logic, thereby reducing cost and improving visual perception.

According to the present specification, it is possible to improve boundary visual perception using a lens gain by designing the size of lenses to increase gradationally from a first pixel region to a second pixel region via a boundary pixel region.

According to the present specification, it is possible to improve reflection visual perception in a lens off state by designing the size of the lenses to increase gradationally from the first pixel region to the second pixel region via the boundary pixel region and additionally arranging a dummy lens on a light transmission part of the boundary pixel region.

According to the present specification, it is possible to improve visual perception by additionally arranging dummy lenses both on a first light transmission part of the boundary pixel region NML and a second light transmission part of the second pixel region UDC, which are provided on a first panel part located at a driver's side of a vehicle and a second panel part located between a driver and a front passenger in a full dash board type display device.

According to the present specification, it is possible to reduce circuit logic by gradationally designing a switchable privacy mode lens (SPML) in a third panel part located at a front passenger side of a vehicle, thereby reducing cost and improving visual perception.

Effects of the present specification are not limited to the above-described effects, and other effects that are not mentioned will be able to be clearly understood by those skilled in the art to which the present specification pertains based on the following description.

The display device according to various embodiments of the present disclosure may be described as follows.

A display panel according to one embodiment of the present disclosure may comprise a first pixel region; a second pixel region; and a boundary pixel region disposed between the first pixel region and the second pixel region, wherein each of the first pixel region, the second pixel region, and the boundary pixel region includes a plurality of pixels composed of a plurality of sub-pixels, each of the boundary pixel region and the second pixel region includes a plurality of light transmission parts between the plurality of sub-pixels, a plurality of first lenses are disposed in the first pixel region, a plurality of second lenses are disposed in the boundary pixel region, and a plurality of third lenses are disposed in the second pixel region, and a size of a lens increases gradationally in an order of the plurality of first lenses, the plurality of second lenses, and the plurality of third lenses.

According to one embodiment of the present disclosure, the first to third lenses may be disposed to have lengths that increase in the order of the first lenses, the second lenses, and the third lenses.

According to one embodiment of the present disclosure, the first to third lenses may be disposed to have thicknesses that increase in the order of the first lenses, the second lenses, and the third lenses.

According to one embodiment of the present disclosure, the first to third lenses may be disposed to have areas that increase in the order of the first lenses, the second lenses, and the third lenses.

According to one embodiment of the present disclosure, each of the first to third lenses may include a stacked structure of a high-refractive material layer and a low-refractive material layer.

According to one embodiment of the present disclosure, each of the first to third lenses may include a plurality of share lenses and switchable privacy mode lenses (SPMLs).

According to one embodiment of the present disclosure, each of the plurality of share lenses may include a bar-typed lens, and each of the plurality of SPMLs includes a hemispherical lens.

According to one embodiment of the present disclosure, the plurality of first lenses may be disposed above the sub-pixels of the first pixel region, the plurality of second lenses are disposed above the sub-pixels of the boundary pixel region, and the plurality of third lenses are disposed above the sub-pixels of the second pixel region.

According to one embodiment of the present disclosure, each of the plurality of first to third lenses may include at least one hemispherical lens and bar-typed lens.

According to one embodiment of the present disclosure, the display panel may further include a plurality of dummy lenses disposed in a first light transmission part of the boundary pixel region.

According to one embodiment of the present disclosure, the display panel may further include a plurality of dummy lenses disposed in a second light transmission part of the second pixel region.

A display device according to one embodiment of the present disclosure may comprise a display panel including a first pixel region, a second pixel region, and a boundary pixel region disposed between the first pixel region and the second pixel region; and a circuit layer connected to pixels disposed in the first pixel region, the second pixel region, and the boundary pixel region of the display panel, wherein each of the pixels of the first pixel region, the second pixel region, and the boundary pixel region includes a plurality of sub-pixels, each of the boundary pixel region and the second pixel region includes a plurality of light transmission parts between the plurality of sub-pixels, a plurality of first lenses are disposed in the first pixel region, a plurality of second lenses are disposed in the boundary pixel region, and a plurality of third lenses are disposed in the second pixel region, and a size of a lens increases gradationally in an order of the plurality of first lenses, the plurality of second lenses, and the plurality of third lenses.

According to one embodiment of the present disclosure, the first to third lenses are disposed to have lengths that increase in the order of the first lenses, the second lenses, and the third lenses.

According to one embodiment of the present disclosure, the first to third lenses are disposed to have thicknesses that increase in the order of the first lenses, the second lenses, and the third lenses.

According to one embodiment of the present disclosure, each of the first to third lenses includes a plurality of share lenses and switchable privacy mode lenses (SPMLs).

According to one embodiment of the present disclosure, the share lens includes a bar-typed lens, and at least one of the SPMLs includes a hemispherical lens.

According to one embodiment of the present disclosure, the plurality of first lenses are disposed above the sub-pixels of the first pixel region, the plurality of second lenses are disposed above the sub-pixels of the boundary pixel region, and the plurality of third lenses are disposed above the sub-pixels of the second pixel region.

According to one embodiment of the present disclosure, each of the plurality of first to third lenses includes at least one hemispherical lens and bar-typed lens.

According to one embodiment of the present disclosure, the display device may further include a plurality of dummy lenses disposed in a first light transmission part of the boundary pixel region.

According to one embodiment of the present disclosure, the display device may further include a plurality of dummy lenses disposed in a second light transmission part of the second pixel region.

What is claimed is:

1. A display panel comprising:
a first pixel region;
a second pixel region; and
a boundary pixel region between the first pixel region and the second pixel region,
wherein each of the first pixel region, the second pixel region, and the boundary pixel region includes a plurality of pixels that comprise a plurality of sub-pixels,
wherein each of the boundary pixel region and the second pixel region includes a plurality of light transmission parts between the plurality of sub-pixels,
wherein a plurality of first lenses are in the first pixel region, a plurality of second lenses are in the boundary pixel region, and a plurality of third lenses are in the second pixel region,
wherein a size of a lens increases gradationally in an order of the plurality of first lenses, the plurality of second lenses, and the plurality of third lenses.

2. The display panel of claim 1, wherein a first lens from the plurality of first lenses, a second lens from the plurality of second lenses, and a third lens from the plurality of third lenses have lengths that increase in an order of the first lens, the second lens, and the third lens.

3. The display panel of claim 1, wherein a first lens from the plurality of first lenses, a second lens from the plurality of second lenses, and a third lens from the plurality of third lenses have thicknesses that increase in the order of the first lens, the second lens, and the third lens.

4. The display panel of claim 1, wherein a first lens from the plurality of first lenses, a second lens from the plurality of second lenses, and a third lens from the plurality of third lenses have areas that increase in the order of the first lens, the second lens, and the third lens.

5. The display panel of claim 1, wherein each of the plurality of first lenses, the plurality of second lenses, and the plurality of third lenses includes a stacked structure of a high-refractive material layer and a low-refractive material layer.

6. The display panel of claim 1, wherein each of the plurality of first lenses, the plurality of second lenses, and the plurality of third lenses includes a plurality of share lenses and switchable privacy mode lenses (SPMLs).

7. The display panel of claim 6, wherein each of the plurality of share lenses includes a bar-typed lens, and each of the plurality of SPMLs includes a hemispherical lens.

8. The display panel of claim 1, wherein the plurality of first lenses are above the plurality of sub-pixels of the first pixel region, the plurality of second lenses are above the plurality of sub-pixels of the boundary pixel region, and the plurality of third lenses are above the plurality of sub-pixels of the second pixel region.

9. The display panel of claim 1, wherein each of the plurality of first lenses, the plurality of second lenses, and the plurality of third lenses includes at least one hemispherical lens and bar-typed lens.

10. The display panel of claim 1, further comprising:
a plurality of dummy lenses in a first light transmission part of the boundary pixel region.

11. The display panel of claim 10, further comprising:
a plurality of dummy lenses in a second light transmission part of the second pixel region.

12. A display device comprising:
a display panel including a first pixel region, a second pixel region, and a boundary pixel region between the first pixel region and the second pixel region; and
a circuit layer connected to pixels in the first pixel region, the second pixel region, and the boundary pixel region of the display panel,
wherein each of the pixels of the first pixel region, the second pixel region, and the boundary pixel region includes a plurality of sub-pixels,
wherein each of the boundary pixel region and the second pixel region includes a plurality of light transmission parts between the plurality of sub-pixels,
wherein a plurality of first lenses are in the first pixel region, a plurality of second lenses are in the boundary pixel region, and a plurality of third lenses are in the second pixel region, and
wherein a size of a lens increases gradationally in an order of the plurality of first lenses, the plurality of second lenses, and the plurality of third lenses.

13. The display device of claim 12, wherein a first lens from the plurality of first lenses, a second lens from the plurality of second lenses, and a third lens from the plurality of third lenses have lengths that increase in the order of the first lens, the second lens, and the third lens.

14. The display device of claim 12, wherein a first lens from the plurality of first lenses, a second lens from the plurality of second lenses, and a third lens from the plurality of third lenses have thicknesses that increase in the order of the first lens, the second lens, and the third lens.

15. The display device of claim 12, wherein each of the plurality of first lenses, the plurality of second lenses, and the plurality of third lenses includes a plurality of share lenses and switchable privacy mode lenses (SPMLs).

16. The display device of claim 15, wherein a share lens from the plurality of share lenses includes a bar-typed lens, and at least one of the SPMLs includes a hemispherical lens.

17. The display device of claim 12, wherein the plurality of first lenses are above the plurality of sub-pixels of the first pixel region, the plurality of second lenses are above the plurality of sub-pixels of the boundary pixel region, and the plurality of third lenses are above the plurality of sub-pixels of the second pixel region.

18. The display device of claim 12, wherein each of the plurality of first lenses, the plurality of second lenses, and the plurality of third lenses includes at least one hemispherical lens and bar-typed lens.

19. The display device of claim 12, further comprising:
a plurality of dummy lenses in a first light transmission part of the boundary pixel region.

20. The display device of claim 19, further comprising:
a plurality of dummy lenses in a second light transmission part of the second pixel region.
